(19) United States
(12) Patent Application Publication
(10) Pub. No.: US 2022/0344126 A1
(43) Pub. Date: Oct. 27, 2022

(54) PART FOR PLASMA PROCESSING APPARATUS, MANUFACTURING METHOD THEREOF, AND PLASMA PROCESSING APPARATUS

(71) Applicant: KYOCERA Corporation, Kyoto-shi, Kyoto (JP)

(72) Inventor: Manpei TANAKA, Higashiomi-shi, Shiga (JP)

(21) Appl. No.: 17/762,648

(22) PCT Filed: Sep. 18, 2020
(86) PCT No.: PCT/JP2020/035434

§ 371 Date: Mar. 22, 2022

(30) Foreign Application Priority Data
Sep. 27, 2019 (JP) 2019-177247

(51) Int. Cl. H01J 37/32; B28B 1/24; B28B 11/24; C01F 17/218; C01F 7/02; C04B 35/10

(52) U.S. Cl. CPC H01J 37/3244; B28B 1/24; B28B 11/243; H01J 37/32568; C01F 17/218; C01F 7/02; C04B 35/10; H01J 2237/334; C04B 2235/3217; C04B 2235/3225

(57) ABSTRACT

A member for a plasma processing apparatus configured of a tubular body composed of a ceramic having a rare earth element oxide, aluminum oxide, or a rare earth element aluminum composite oxide as a main constituent and including a through hole in an axial direction, in which a number of recessed portions having a depth of from 10 μm to 20 μm, the depth starting from a ridge located between an inner peripheral surface of the tubular body and a target observation surface obtained by polishing from an outer peripheral surface of the tubular body toward an axis, is 2 or less per 1 mm of the ridge.

### TECHNICAL FIELD

The present disclosure relates to a member for a plasma processing apparatus, a manufacturing method thereof, and a plasma processing apparatus.

### BACKGROUND ART

Conventionally, plasma is used to treat an object to be treated in the steps of etching or film formation processing when manufacturing a semiconductor or a liquid crystal. In such steps, a corrosive gas containing a highly reactive halogen element such as fluorine or chlorine is used. Therefore, high corrosion resistance is required for members that are used in a semiconductor or liquid crystal manufacturing device and that come into contact with a corrosive gas or its plasma.

Patent Document 1 proposes a ceramic gas nozzle composed of a Y₂O₃ sintered compact as an example of such a member. The inner surface of the ceramic gas nozzle where a corrosive gas passes through is a fired surface, while the outer surface of the ceramic gas nozzle, which is exposed to the corrosive gas or its plasma, is roughened.

Patent Document 1 describes a method for obtaining the gas nozzle as below. According to the description, first, ion-exchanged water and a binder are added to a Y₂O₃ raw material having a purity of 99.9% to form a slurry, which is then granulated with a spray dryer to obtain a granulated powder. The resulting granulated powder is pressed at a pressure of 1500 kgf/cm² and formed into a nozzle shape, and is then used as a base processed product. The base processed product is subjected to calcination at 900° C. to decompose the binder, followed by firing in a hydrogen atmosphere at 1800° C. The inner surface where a reactive gas passes through is left in the state of a fired surface while the outer surface is roughened by blasting. Thus, the gas nozzle is obtained.

### CITATION LIST

### Patent Literature

Patent Document 1: JP 2007-63595 A

### SUMMARY

A member for a plasma processing apparatus according to the present disclosure is a tubular body, composed of a ceramic having a rare earth element oxide, aluminum oxide, or a rare earth element aluminum composite oxide as a main constituent and including a through hole in an axial direction, wherein the number of recessed portions having a depth of from 10 μm to 20 μm, starting from a ridge located between an inner peripheral surface of the tubular body and a target observation surface obtained by polishing from an outer peripheral surface of the tubular body toward an axis, is 2 or less per 1 mm of the ridge.

A manufacturing method of the member for a plasma processing apparatus according to the present disclosure includes: housing a powder, a wax, a dispersing agent, and a plasticizer in a container and stirring to obtain a slurry, the powder containing a rare earth element oxide, aluminum oxide, or a rare earth element aluminum composite oxide having a 95 vol % cumulative particle size on the cumulative distribution curve of 6.5 μm or less as a main constituent; preheating the slurry; defoaming the preheated slurry; performing injection molding using the slurry to obtain a molded article having a cylindrical shape; and firing the molded article.

The plasma processing apparatus according to the present disclosure is provided with the member for a plasma processing apparatus and a plasma generating apparatus.

### BRIEF DESCRIPTION OF DRAWINGS

FIG. 1A is a cross-sectional view illustrating a portion of a plasma processing apparatus provided with an upper electrode having a gas-flow passage tube, the gas-flow passage tube being a member for a plasma processing apparatus that is a tubular body according to the present disclosure.

FIG. 1B is an enlarged view of the portion Ain FIG. 1A.

FIG. 2A is a perspective view illustrating a target observation surface of a member for a plasma processing apparatus according to an embodiment of the present disclosure.

FIG. 2B is an enlarged schematic view of the portion B in FIG. 2A.

FIG. 3A is a photomicrograph (magnification of 20 times) showing a target observation surface of a member for a plasma processing apparatus that is Sample No. 1 of the Examples.

FIG. 3B is an enlarged photomicrograph (magnification of 200 times) of the portion D in FIG. 3A.

FIG. 4A is a photomicrograph (magnification of 20 times) showing a target observation surface of a member for a plasma processing apparatus that is Sample No. 4 (Comparative Example) of the Examples.

FIG. 4B is an enlarged photomicrograph (magnification of 200 times) of the portion E in FIG. 4A.

### DESCRIPTION OF EMBODIMENTS

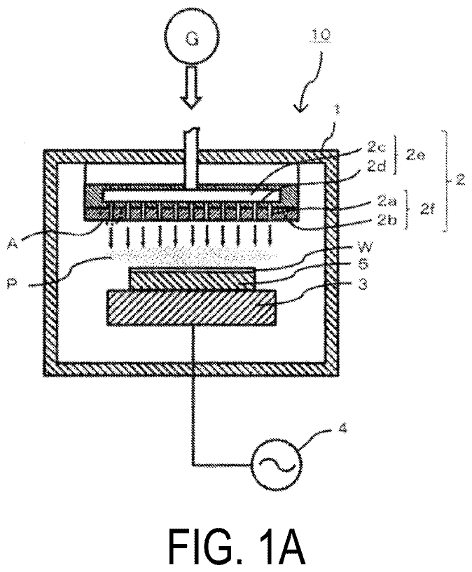

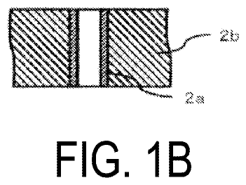

Hereinafter, a member for a plasma processing apparatus, a manufacturing method, and a plasma processing apparatus according to the present disclosure will be described with reference to the drawings. FIG. 1A is a cross-sectional view illustrating a portion of a plasma processing apparatus provided with an upper electrode having a tubular body composed of a member for a plasma processing apparatus according to the present disclosure, the tubular body being a gas-flow passage tube. FIG. 1B is an enlarged view of the portion A in FIG. 1A.

A plasma processing apparatus 10 according to the present disclosure illustrated in FIGS. 1A and 1B is, for example, a plasma etching device including a chamber 1 in which a to-be-treated member W, such as a semiconductor wafer, is placed inside. An upper electrode 2 is disposed on the top side of the inside of the chamber 1 while a lower electrode 3 is disposed on the bottom side of the inside of the chamber 1, the upper electrode 2 and the lower electrode 3 facing each other.

The upper electrode 2 includes an electrode plate 2b and a holding member 2e. The electrode plate 2b includes a plurality of tubular bodies 2a (gas-flow passage tubes) which supplies a plasma generating gas G to the inside of the chamber 1. The holding member 2e includes a diffusing portion 2c, which is an internal space in which the plasma generating gas G is diffused, and a plurality of introduction holes 2d, which introduces the diffused plasma generating gas G into the tubular body 2a.

Further, a high frequency power supply 4 supplies high frequency power, turning the plasma generating gas G, which is discharged as a shower from the tubular bodies 2a, into a plasma, to thereby form a plasma zone P. Note that the electrode plate 2b and the tubular bodies 2a may be collectively referred to as a shower plate 2f.

Note that in FIG. 1A, only the position of the tubular bodies 2a is illustrated because of the small size of the tubular bodies 2a, and a detailed configuration of each tubular body 2a is illustrated in FIG. 1B.

Of these members, for example, the upper electrode 2, the lower electrode 3, and the high frequency power supply 4 constitute a plasma generating apparatus.

Here, examples of the plasma generating gas G include fluorine-based gas such as SF₆, CF₄, CHF₃, ClF₃, NF₃, C₄F₈, and HF, and chlorine-based gas such as Cl₂, HCl, BCl₃, and CCl₄. The tubular body 2a is an example of the member for a plasma processing apparatus.

The lower electrode 3 is, for example, a susceptor made of aluminum. An electrostatic chuck 5 is placed on the susceptor and holds the to-be-treated member W by an electrostatic adsorption force.

Then, a coating film formed on the surface of the to-be-treated member W is etched by the ions or radicals contained in the plasma.

The tubular body 2a, which is the member for a plasma processing apparatus according to the present disclosure, is composed of, for example, a cylindrical-shaped ceramic having a rare earth element oxide, aluminum oxide, or a rare earth element aluminum composite oxide as a main constituent; the inner peripheral surface and the end face on the discharge side of the tubular body 2a are surfaces exposed to the plasma generating gas G. In the following description, a ceramic containing a rare earth element oxide as a main constituent is referred to as a rare earth element oxide sintered compact, while a ceramic containing aluminum oxide as a main constituent is referred to as an aluminum oxide sintered compact.

The tubular body 2a has, for example, an outer diameter of from 2 mm to 5 mm, an inner diameter of from 0.3 mm to 0.75 mm, and a length of from 3 mm to 8 mm.

In the present disclosure, a main constituent refers to a constituent that accounts for 70 mass % or greater of the total of 100 mass % of the constituents of a ceramic.

The member for a plasma processing apparatus according to the present disclosure may contain 98 mass % or greater of a rare earth element oxide or aluminum oxide having high corrosion resistance to the plasma generating gas G.

The higher the content of the rare earth element oxide in the rare earth element oxide sintered compact, the higher the corrosion resistance. In particular, the content of the rare earth element oxide may be 99.0 mass % or greater, 99.5 mass % or greater, or further 99.9 mass % or greater.

Examples of the rare earth element oxide include Y₂O₃, Er₂O₃, Gr₂O₃, Nd₂O₃, La₂O₃, Dy₂O₃, CeO₂, and ScO₃.

In addition to the rare earth element oxide, the rare earth element oxide sintered compact may contain, for example, at least one element selected from silicon, iron, aluminum, calcium, and magnesium. The silicon content may be not greater than 300 mass ppm in terms of SiO₂, the iron content may be not greater than 50 mass ppm in terms of Fe₂O₃, the aluminum content may be not greater than 100 mass ppm in terms of Al₂O₃, and the total content of calcium and magnesium may be not greater than 350 mass ppm in terms of CaO and MgO, respectively. Furthermore, the content of carbon may be 100 mass ppm or less.

The higher the content of aluminum oxide in the aluminum oxide sintered compact, the higher the corrosion resistance. In particular, the content of aluminum oxide may be 99.0 mass % or greater, 99.5 mass % or greater, or further 99.9 mass % or greater.

In addition to aluminum oxide, the aluminum oxide sintered compact may contain, for example, at least one element selected from silicon, iron, calcium, and magnesium. The content of silicon may be 300 mass ppm or less in terms of SiO₂, the content of iron may be 50 mass ppm or less in terms of Fe₂O₃, and the total content of calcium and magnesium may be 350 mass ppm or less in terms of CaO and MgO, respectively. Furthermore, the content of carbon may be 100 mass ppm or less.

The presence of the rare earth element oxide can be identified and confirmed by an X-ray diffractometer using a CuKα beam, and the content of each constituent can be determined by, for example, an inductively coupled plasma (ICP) emission spectrophotometer or a fluorescent X-ray analyzer. In addition, the content of carbon may be determined using a carbon analyzer.

The presence of aluminum oxide can be determined in the same manner as for the rare earth element oxide.

Further, the member for a plasma processing apparatus according to the present disclosure may be a ceramic containing aluminum oxide and a rare earth element aluminum composite oxide in which either aluminum oxide or the rare earth element aluminum composite oxide is the main constituent.

In this case, aluminum oxide is a constituent that ensures the mechanical characteristics of the ceramic, while the rare earth element aluminum composite oxide is a constituent that exhibits high corrosion resistance to an etching gas that is a plasma generated from the plasma generating gas G. Examples of the rare earth element aluminum composite oxide include: yttrium aluminum composite oxides such as YAG(3Y₂O₃.5Al₂O₃), YAM(2Y₂O₃.Al₂O₃), YAL(Y₂O₃.Al₂O₃), and YAP(YAlO₃); erbium aluminum composite oxides such as EAG(Er₃Al₅O₁₂), EAM(Er₄Al₂O₉), and EAP(ErAlO₃); gadolinium aluminum composite oxides such as GdAM(Gd₄Al₂O₉) and GdAP(GdAlO₃); and neodymium aluminum composite oxides such as NdAG(Nd₃Al₅O₁₂), NdAM(Nd₄Al₂O₉), and NdAP(NdAlO₃).

Here, when the member for a plasma processing apparatus is composed of a ceramic containing either aluminum oxide or an yttrium aluminum composite oxide as the main constituent, for example, the content of aluminum is preferably from 70 mass % to 98 mass % in terms of Al₂O₃, while the content of yttrium is preferably from 2 mass % to 30 mass % in terms of Y₂O₃.

Note that, although a ceramic containing a rare earth element oxide, aluminum oxide, or a rare earth element aluminum composite oxide as a main constituent as described above are all polycrystals, a ceramic containing a rare earth oxide, aluminum oxide, or a rare earth element aluminum composite oxide as a main constituent may be a single crystal.

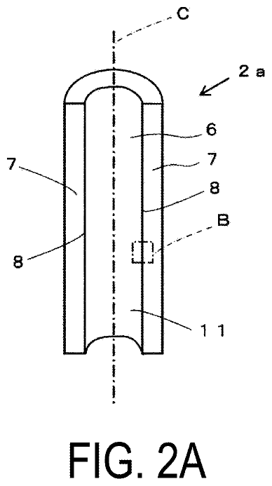

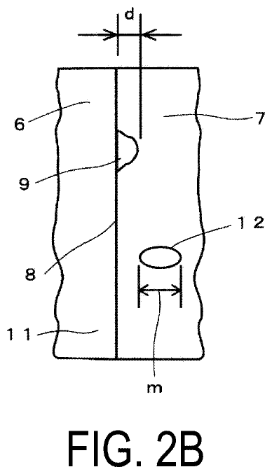

FIG. 2A and FIG. 2B, which is a partially enlarged view of FIG. 2A, illustrate a state in which the tubular body 2a, which is the member for a plasma processing apparatus according to the present disclosure, is polished from the outer peripheral surface of the tubular body 2a toward an axis C. According to the present disclosure, when the obtained polished surface is used as a target observation surface 7, the number of recessed portions 9 each having a depth d from 10 μm to 20 μm is 2 or less, preferably 1 or less, per 1 mm of a ridge 8, the starting point of the depth d being a ridge 8 located between an inner peripheral surface 6 of the tubular body 2a and the target observation surface 7, the tubular body 2a being the member for a plasma processing apparatus. The recessed portion 9 has, for example, a depressed shape. The reason for polishing the tubular body 2a from the outer peripheral surface toward the axis C is to facilitate the measurement of the depth of the recessed portion 9. The direction of the depth d is a direction in the target observation surface 7 that starts from the ridge 8 and proceeds toward an outer edge, the outer edge being the boundary between the outer peripheral surface and the target observation surface 7.

Here, the arithmetic mean roughness (Ra) of the target observation surface 7 is, for example, from 0.01 μm to 0.1 μm. The arithmetic mean roughness (Ra) may be determined in accordance with JIS B 0601:2013. Further, in order to obtain the target observation surface 7, WA (white alundum) having an average particle size (D₅₀) of 1 μm may be used as the abrasive, and a polisher having a pitch may be used as the polishing disc.

Note that, in the case of a tubular body having a thickness of 3 mm or greater, polishing may be performed after grinding the tubular body 2a from the outer peripheral surface toward the axis until a polishing margin of from 0.1 mm to 0.2 mm is left.

Then, for an image (for example, 2.3 mm in the lateral direction and 1.7 mm in the longitudinal direction) obtained by photographing the target observation surface 7 with a scanning electron microscope, for example, a free software called “Hasamu Monosashi (Inserted Ruler)” may be used to measure the depth d of the recessed portion, and the number of the recessed portions 9 having a depth d of from 10 μm to 20 μm may be counted.

Here, the depth of the recessed portion 9 is set to 10 μm or grater because a depth of 10 μm is the minimum value, or the threshold value, at which particles that are chipped off and float to have a significant adverse effect on the plasma zone P.

As such, there is almost no presence of the recessed portion 9 on the inner peripheral surface 6 of the tubular body 2a, and thus the generation of chipping starting from the inner peripheral surface 6 is suppressed. As a result, even when the plasma generating gas G passes through a through hole 11, the possibility of separated grains becoming new particles and floating in the plasma zone P can be reduced.

Here, the recessed portion 9 is, in other words, a recessed portion 9 that is open to the inner peripheral surface 6 of the tubular body 2a.

In addition, on the target observation surface 7, the straightness of the ridge 8 is preferably 20 μm or less. Straightness refers to the degree of deviation of the ridge 8 from a geometrically straight line. The straightness of the ridge 8 can be measured by using a free software called “Hasamu Monosashi (Inserted Ruler)” to measure an image (for example, 1.2 mm in the lateral direction and 1.4 mm in the longitudinal direction) obtained by photographing the target observation surface 7 with an optical microscope. Here, the axial direction of the tubular body 2a may be aligned with the longitudinal direction of the image, and at least one of the left and right ridges sandwiching the inner peripheral surface may be included in the image; the length of the geometrically straight line may be 1.4 mm.

In the present disclosure, when the straightness of the ridge 8 is 20 μm or less, there is no presence of a large depressed recessed portion 9 on the inner peripheral surface 6. Thus, even if the flow of the plasma generating gas G is turbulent, the possibility of new particles floating in the plasma zone P is reduced.

Furthermore, on the target observation surface 7, a maximum diameter m of a closed pore 12 located within 0.1 mm from the ridge 8 toward the outer edge, the outer edge being the boundary between the outer peripheral surface of the tubular body 2a and the target observation surface 7, is preferably 0.9 μm or less. That is, since there is no presence of a large closed pore 12 in the vicinity of the inner peripheral surface 6, even after repeated heating and cooling, cracks are less likely to occur from the closed pore 12 toward the inner peripheral surface 6, and the possibility of particles generated by this crack floating in the plasma zone P is reduced.

The maximum diameter m of the closed pore 12 can be measured by using, for example, a free software called “Hasamu Monosashi (Inserted Ruler)” to measure an image (for example, 1.2 mm in the lateral direction and 1.4 mm in the longitudinal direction) obtained by photographing the target observation surface 7 with an optical microscope. Here, the axial direction of the tubular body 2a is aligned with the longitudinal direction of the image, and at least one of the left and right ridges 8 sandwiching the inner peripheral surface is included in the image.

The inner peripheral surface 6 of the tubular body 2a may be a fired surface having a root mean square slope (RΔqi) of 1.3 or less.

With such a configuration, the inner peripheral surface 6 does not contain a broken layer, and the root mean square slope (RΔqi) is controlled. Thus, even when the plasma generating gas G passes through the through hole 11 and the separated grains are fine grains, the possibility of the separated grains becoming new particles and floating in the plasma zone P can be reduced.

The inner peripheral surface 6 of the tubular body 2a may be a fired surface having a section height difference (Rδci), which represents a difference between a section height at a material ratio of 25% in a roughness profile and a section height at a material ratio of 75% in the roughness profile, of 1.7 μm or less.

With such a configuration, the inner peripheral surface 6 does not contain a broken layer, and the section height difference (Rδci) is controlled. Thus, even when the plasma generating gas G passes through the through hole 11 and the separated grains are fine grains, the possibility of the separated grains becoming new particles and floating in the plasma zone P can be further reduced.

In particular, the inner peripheral surface 6 is preferably a fired surface having a section height difference (Rδci) of 1.4 μm or less.

With such a configuration, the outer peripheral surface does not contain a broken layer; meanwhile, when the tubular body 2a is adhered to the upper electrode 2 with an adhesive or the like, an appropriate anchor effect can be obtained. Thus, high reliability can be obtained over a long period of time.

The outer peripheral surface of the tubular body 2a may be a fired surface having a section height difference (Rδco), which represents a difference between a section height at a material ratio of 25% in a roughness profile and a section height at a material ratio of 75% in the roughness profile, of 0.04 μm or greater.

With such a configuration, the outer peripheral surface does not contain a broken layer, and hydrophilicity is improved. Thus, for example, when the tubular body 2a is fixed to the electrode plate 2b using a hydrophilic epoxy adhesive, high reliability can be obtained over a long period of time.

In particular, the outer peripheral surface is preferably a fired surface having a section height difference (Rδco) of 0.26 μm or greater.

The root mean square slopes (RΔqi, RΔqo) and the section height differences (Rδci, Rδco) can be measured in accordance with JIS B 0601:2001 using a shape analysis laser microscope (available from Keyence Corporation, VK-X1100 or a successor model thereof). As the measurement conditions, first, the illumination method is preferably coaxial vertical illumination, the magnification is preferably 480 times, the cutoff value λs is preferably none, the cutoff value λc is preferably 0.08 mm, the cutoff value λf is preferably none, and the correction of termination effect is preferably enabled. The measurement range per location on the inner peripheral surface 6 to be measured and the outer peripheral surface to be measured is preferably set to, for example, 710 μm×533 μm. For each measurement range, four lines to be measured are preferably drawn at substantially equal intervals along the longitudinal direction of the measurement range to measure the line roughness. The measurement ranges include a total of two locations, one in the central portion in each axial direction, and the length to be measured is, for example, 560 μm.

Next, a manufacturing method of the tubular body 2a that is a member for a plasma processing apparatus according to the present embodiment will be described. First, to produce a member for a plasma processing apparatus composed of an yttrium oxide sintered compact, which is an example of a rare earth element oxide sintered compact, a powder containing yttrium oxide as a main constituent, a wax, a dispersing agent, and a plasticizer are prepared.

The powder containing yttrium oxide as a main constituent (hereinafter referred to as yttrium oxide powder) to be used preferably has a purity of 99.9 mass % or greater and a 95 vol % cumulative particle size on the cumulative distribution curve of 6.5 μm or less, more preferably 6 μm or less. When the 95 vol % cumulative particle size is within this range, the resulting sintered compact contains less pores, and generation of the recessed portion 9 on the inner peripheral surface 6 is suppressed, making it possible to reduce the generation of particles.

Here, a cumulative distribution curve is a curve in a two-dimensional graph showing the cumulative distribution of particle size with the horizontal axis representing the particle size and the vertical axis representing the cumulative percentage of the particle size. A cumulative distribution curve can be obtained by a laser diffraction/scattering method using, for example, a particle size distribution measuring device available from MicrotracBEL Corp. (MT3300 or a successor model thereof).

With respect to 100 parts by mass of the powder containing yttrium oxide as a main constituent (hereinafter referred to as yttrium oxide powder), the wax is from 13 parts by mass to 14 parts by mass, the dispersing agent is from 0.4 parts by mass to 0.5 parts by mass, and the plasticizer is from 1.4 parts by mass to 1.5 parts by mass.

Then, the yttrium oxide powder, the wax, the dispersing agent, and the plasticizer are all heated to 90° C. or higher, and are housed in a resin container. At this time, the wax, the dispersing agent, and the plasticizer are liquids. For example, the yttrium oxide powder, the wax, the dispersing agent, and the plasticizer may be heated to from 90° C. to 140° C. and housed in the resin container.

Next, the container is placed on a stirrer and subjected to rotation-and-revolution for 3 minutes (rotation-and-revolution kneading process), whereby the yttrium oxide powder, the wax, the dispersing agent, and the plasticizer are stirred to obtain a slurry. Then, the resulting slurry is filled into a syringe and subjected to a defoaming process in which the syringe is subjected to rotation-and-revolution for 1 minute with the use of a defoaming jig. Here, the slurry is preferably pre-heated at from 120° C. to 180° C. before the defoaming process.

Next, the syringe filled with the defoamed slurry is mounted to an injection molding machine and the slurry is molded while the temperature of the slurry is maintained at 90° C. or higher, resulting in a molded article having a cylindrical shape. Here, a columnar core forming the inner peripheral surface of the molded article having a cylindrical shape is mounted to the injection molding machine prior to the molding. In addition, a channel through which the slurry passes in the injection molding machine is also preferably maintained at 90° C. or higher.

By sequentially degreasing and firing the obtained molded article, an yttrium oxide sintered compact having a cylindrical shape can be obtained. Here, the firing atmosphere is preferably an air atmosphere, the firing temperature is preferably from 1600° C. to 1800° C., and the retention time is preferably from 2 hours to 4 hours.

In addition, the firing temperature is preferably from 1620° C. to 1800° C. while the retention time is preferably from 3 hours to 4 hours for obtaining an yttrium oxide sintered compact in which the maximum diameter of a closed pore is 0.9 μm or less, the closed pore being on the target observation surface and located within 0.1 mm from the ridge toward the outer edge which is the boundary between the outer peripheral surface of the tubular body and the target observation surface.

A member for a plasma processing apparatus composed of another rare earth element oxide sintered compact can also be produced in the same manner as the member for a plasma processing apparatus composed of an yttrium oxide sintered compact.

A rare earth element oxide sintered compact having a cylindrical shape obtained by the above manufacturing method preferably has 2 or less of the recessed portions 9 per 1 mm of the ridge 8, the recessed portion 9 having a depth, which starts from the ridge 8, of from 10 μm to 20 μm.

In addition, by keeping the straightness of the outer peripheral surface of the core used in injection molding at 15 μm or less, the straightness of the ridge 8 can be kept at 20 μm or less.

Therefore, when the member for a plasma processing apparatus composed of a rare earth element oxide sintered compact having a cylindrical shape described above is used as a gas-flow passage tube or the like, the generation of chipping starting from the inner peripheral surface 6 can be suppressed.

A member for a plasma processing apparatus composed of an aluminum oxide sintered compact can be produced in the same manner as the member for a plasma processing apparatus composed of an yttrium oxide sintered compact. However, it is preferable to change only the firing temperature to from 1500° C. to 1700° C.

In addition, the firing temperature is preferably from 1520° C. to 1700° C. while the retention time is preferably from 3 hours to 4 hours for obtaining an aluminum oxide sintered compact in which the maximum diameter of a closed pore is 0.9 μm or less, the closed pore being on the target observation surface and located within 0.1 mm from the ridge toward the outer edge which is the boundary between the outer peripheral surface of the tubular body and the target observation surface.

It should be noted that the description of the above embodiments of the present disclosure is presented for purposes of exemplification and description, and is not intended to limit the present invention in the forms disclosed in the embodiments. It is self-evident that many modifications and variations are possible in view of the above teachings. The scope of the present invention is intended to be defined by the appended claims and their equivalents. For example, in the example illustrated in FIG. 1A, the tubular body 2a, which is a member for a plasma processing apparatus, is a gas-flow passage tube disposed within the chamber 1 for generating a stable plasma from the plasma generating gas G. However, the tubular body 2a may be a member for supplying the plasma generating gas G to the chamber 1, or a member for discharging the plasma generating gas G from the chamber 1.

Hereinafter, examples of the present disclosure will be specifically described; however, the present disclosure is not limited to these examples.

### Example 1

An yttrium oxide powder having a purity of 99.99 mass % and an aluminum oxide powder having a purity of 99.99 mass % were used and mixed in accordance with the ratios shown in Table 1 to prepare raw material powders. Each of the raw material powders, a wax, a dispersing agent, and a plasticizer were heated to 90° C., and then placed in resin containers and mixed. Next, the containers were placed at predetermined positions of the stirrer, and the containers were subjected to rotation-and-revolution for 3 minutes (rotation-and-revolution kneading process) to obtain slurries.

Here, with respect to 100 parts by mass of each of the raw material powders, 13.5 parts by mass of the wax, 0.45 parts by mass of the dispersing agent, and 1.45 parts by mass of the plasticizer were used.

The resulting slurries were filled into syringes and subjected to a defoaming process in which the syringes were subjected to rotation-and-revolution for 1 minute with the use of a defoaming jig. Next, the syringes were mounted to an injection molding machine and the slurries were molded while the temperature of the slurries was maintained at 90° C. or higher, resulting in molded articles having a cylindrical shape. Here, columnar cores forming the inner peripheral surfaces of the molded articles each having a cylindrical shape were mounted to the injection molding machine prior to the molding. The straightness of the outer peripheral surface of any of the cores was set to from 20 μm to 25 μm. At this time, the channels of the slurries in the injection molding machine were also maintained at 90° C. or higher.

The resulting molded articles were sequentially degreased and fired, resulting in sintered compacts each having a cylindrical shape (Samples No. 1-12) serving as gas-flow passage tubes. Here, the firing atmosphere was an air atmosphere, and the firing temperatures and the holding times were as shown in Table 1.

The presence of yttrium oxide or aluminum oxide in each sample was confirmed by an X-ray diffractometer using a CuKα beam. Furthermore, as a result of measuring the content of each metal element with an inductively coupled plasma (ICP) emission spectrophotometer, it was found that the content of yttrium or aluminum was the highest in any of the samples.

For each sample shown in Table 1, the particle size of the raw material powder, the characteristic value of the sintered compact, and the corrosion resistance to plasma (number of particles generated) were measured by the following methods.

(1) 95 vol % cumulative particle size on cumulative distribution curve

The 95 vol % cumulative particle size on the cumulative distribution curve was measured using a particle size distribution measuring device available from MicrotracBEL Corporation (MT3300).

(2) Number of recessed portions starting from ridge located between inner peripheral surface and target observation surface

First, the tubular body 2a was polished from the outer peripheral surface toward the axis C to obtain a target observation surface having an arithmetic mean roughness Ra of from 0.01 μm to 0.1 μm.

Then, for an image (2.3 mm in the lateral direction and 1.7 mm in the longitudinal direction) obtained by photographing the target observation surface 7 with a scanning electron microscope, a free software “Hasamu Monosashi (Inserted Ruler)” was used to measure the depth d of the recessed portion, and the number of the recessed portions 9 having a depth d of from 10 μm to 20 μm was counted.

(3) Number of particles generated when pure water is supplied to through hole of each sample and discharged

A container was connected to the opening portion on the discharge side of the through hole of each sample. Next, pure water was supplied for 100 seconds from the opening portion on the supply side of the through hole at a flow rate of 5 mL/sec. The number of particles contained in the pure water discharged into the container was then measured using a liquid particle counter (LPC). Note that the particles measured were particles having a diameter exceeding 0.2 μm. Furthermore, before being connected, the container was subjected to ultrasonic cleaning and the number of particles having a diameter exceeding 0.2 μm was confirmed to be 20 or less.

The results of these measurements are shown in Table 1.

TABLE 1

| | Raw material powder | | | | | Gas-flow passage tube | |
|---|---|---|---|---|---|---|---|
| | | | 95 vol % | | | Number of | Number of |
| | Y₂O₃ | Al₂O₃ | cumulative | Firing | Hold | recessed | particles |
| Sample | ratio | ratio | particle size | temperature | time | portions/mm | generated |
| No. | (mass %) | (mass %) | (μm) | (° C.) | (h) | (number) | (number) |
| 1 | 100 | 0 | 5.8 | 1700 | 3 | 0 | 1020 |
| 2 | 100 | 0 | 6 | 1700 | 3 | 1 | 1458 |
| 3 | 100 | 0 | 6.5 | 1700 | 3 | 2 | 1984 |
| *4 | 100 | 0 | 7 | 1700 | 3 | 4 | 2813 |
| 5 | 0 | 100 | 5.5 | 1600 | 3 | 1 | 1003 |
| 6 | 0 | 100 | 5.9 | 1600 | 3 | 1 | 1450 |
| 7 | 0 | 100 | 6.5 | 1600 | 3 | 2 | 1985 |
| *8 | 0 | 100 | 7.1 | 1600 | 3 | 4 | 2834 |
| 9 | 20 | 80 | 5.7 | 1600 | 3 | 1 | 1014 |
| 10 | 20 | 80 | 6 | 1600 | 3 | 1 | 1460 |
| 11 | 20 | 80 | 6.5 | 1600 | 3 | 2 | 1979 |
| *12 | 20 | 80 | 7.1 | 1600 | 3 | 4 | 2845 |

*Comparative example.

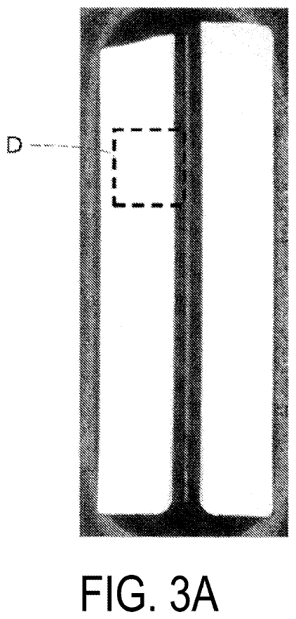

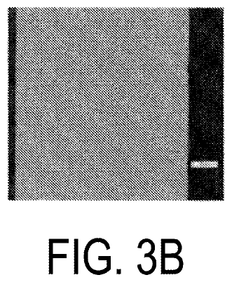

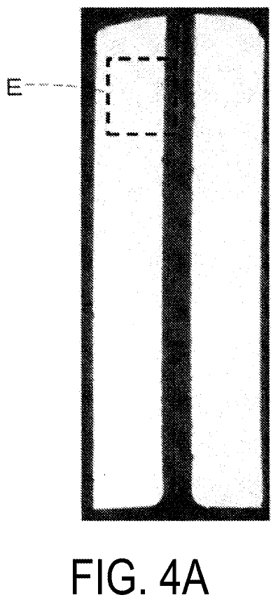

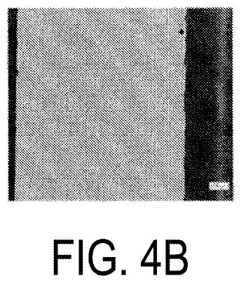

In addition, a photomicrograph showing the target observation surface of the gas-flow passage tube of Sample No. 1 is shown in FIG. 3A, and an enlarged photomicrograph of the portion D thereof is shown in FIG. 3B. A photomicrograph showing the target observation surface of the gas-flow passage tube of Sample No. 4 is shown in FIG. 4A, and an enlarged photomicrograph of the portion D thereof is shown in FIG. 4B.

As shown in Table 1, in Samples Nos. 1 to 3, 5 to 7, and 9 to 11, the number of recessed portions having a depth of from 10 μm to 20 μm is 2 or less per 1 mm of the ridge; as such, it can be said that these samples have a small number of generated particles and a high corrosion resistance to plasma.

The small number of particles in Sample No. 1 is clear from the photomicrographs in FIGS. 3B and 4B which show enlarged views of the target observation surfaces of Samples No. 1 and No. 4 (comparative example), respectively. Further, when comparing FIGS. 3B and 4B, it can be seen that the diameter of the closed pore in Sample No. 1 is also smaller than that in Sample No. 4.

### Example 2

By the same method as that described in Example 1, molded articles each having a cylindrical shape and containing yttrium oxide as a main constituent were obtained. Here, columnar cores forming the inner peripheral surfaces of the molded articles each having a cylindrical shape were mounted to the injection molding machine prior to the molding. In addition, an yttrium oxide powder having a 95 vol % cumulative particle size of 6.5 μm on the cumulative distribution curve, as measured using a particle size distribution measuring device available from MicrotracBEL Corporation (MT3300), was formed.

The straightness of the outer peripheral surfaces of the cores were as shown in Table 2.

The resulting molded articles were sequentially degreased and fired, resulting in sintered compacts each having a cylindrical shape (Samples No. 13-16) serving as gas-flow passage tubes. Here, the firing atmosphere was an air atmosphere, the firing temperature was 1700° C., and the retention time was 3 hours.

The straightness of the ridges was measured using a free software “Hasamu Monosashi (Inserted Ruler)” to measure images (1.2 mm in the lateral direction and 1.4 mm in the longitudinal direction) obtained by photographing the target observation surfaces with an optical microscope. Here, the axial direction of the gas-flow passage tubes was aligned with the longitudinal direction of the images, and the left and right ridges sandwiching the inner peripheral surfaces were included in the images; the length of the geometrically straight lines was 1.4 mm, and Table 2 shows the values of the straightness of the left or right ridges, whichever is higher.

Then, the number of particles generated when pure water was supplied to the through hole of each sample and discharged was measured in the same manner as in the method described in Example 1 and presented in Table 2. In each of the Samples No. 13 to 16, the number of recessed portions having a depth of from 10 μm to 20 μm was 2 or less per 1 mm of the ridge.

TABLE 2

| | Straightness of | Gas-flow passage tube | |
|---|---|---|---|
| | outer peripheral | Straightness | Number of |
| Sample | surface of core | of ridge | particles generated |
| No. | (μm) | (μm) | (number) |
| 13 | 10 | 15 | 1297 |
| 14 | 12 | 17 | 1338 |
| 15 | 15 | 20 | 1350 |
| 16 | 20 | 25 | 1462 |

As presented in Table 2, the straightness of the ridge in Nos. 13 to 15 is 20 μm or less. Thus, it can be said that these samples have a small number of generated particles and a higher corrosion resistance to plasma when compared to No. 16.

### Example 3

By the same method as that described in Example 1, molded articles each having a cylindrical shape and containing yttrium oxide as a main constituent were obtained. Here, columnar cores forming the inner peripheral surfaces of the molded articles each having a cylindrical shape were mounted to the injection molding machine prior to the molding. Then, an yttrium oxide powder having a 95 vol % cumulative particle size of 5.5 μm on the cumulative distribution curve, as measured using a particle size distribution measuring device available from MicrotracBEL Corporation (MT3300), was formed.

The straightness of the outer peripheral surface of any of the cores was set to 15 μm or smaller.

The resulting molded articles were sequentially degreased and fired, resulting in sintered compacts each having a cylindrical shape (Samples No. 17-20) serving as gas-flow passage tubes. Here, the firing atmosphere was an air atmosphere, the firing temperatures were as presented in Table 3, and the retention time was 3 hours.

The maximum diameters of closed pores within 0.1 mm from the ridges to the outer edges of the tubular bodies were measured using a free software “Hasamu Monosashi (Inserted Ruler)” on images (1.2 mm in the lateral direction and 1.4 mm in the longitudinal direction) obtained by photographing the target observation surfaces with an optical microscope. The axial direction of the gas-flow passage tubes was aligned with the longitudinal direction of the images, and the left and right ridges sandwiching the inner peripheral surfaces were included in the images.

Then, the number of particles generated when pure water was supplied to the through hole of each sample and discharged was measured in the same manner as in the method described in Example 1. In each of the Samples No. 17 to 20, the number of recessed portions having a depth of from 10 μm to 20 μm was 2 or less per 1 mm of the ridge.

TABLE 3

| | Firing | Maximum diameter | Number of |
|---|---|---|---|
| Sample | temperature | of closed pore | particles generated |
| No. | (° C.) | (μm) | (Number) |
| 17 | 1720 | 0.68 | 1250 |
| 18 | 1670 | 0.78 | 1268 |
| 19 | 1620 | 0.9 | 1279 |
| 20 | 1600 | 1.09 | 1298 |

As presented in Table 3, in Samples No. 17 to 19, the maximum diameter of a closed pore within 0.1 mm from the ridge toward the outer edge was 0.9 μm or less. Thus, it can be said that Samples No. 17 to 19 have a small number of particles generated and a higher corrosion resistance to plasma when compared to No. 20.

### REFERENCE SIGNS LIST

1 Chamber
2 Upper electrode
2a Tubular body (member for plasma processing apparatus)
2b Electrode plate
2c Diffusing portion
2d Introduction hole
2e Holding member
2f Shower plate
3 Lower electrode
4 High frequency power supply
5 Electrostatic chuck
6 Inner peripheral surface
7 Target observation surface
8 Ridge
9 Recessed portion
10 Plasma processing apparatus
11 Through hole
12 Closed pore

1. A member for a plasma processing apparatus, comprising:
a tubular body composed of a ceramic having a rare earth element oxide, aluminum oxide, or a rare earth element aluminum composite oxide as a main constituent, the tubular body including
a through hole in an axial direction and
a number of recessed portions having a depth of from 10 μm to 20 μm, the depth starting from a ridge located between an inner peripheral surface of the tubular body and a target observation surface of the tubular body, wherein the target observation surface is obtained by polishing from an outer peripheral surface of the tubular body toward the axis, wherein the number of the recessed portions is 2 or less per 1 mm of the ridge.

2. The member for a plasma processing apparatus according to claim 1, wherein a straightness of the ridge on the target observation surface is 20 μm or less.

3. The member for a plasma processing apparatus according to claim 1, wherein a maximum diameter of a closed pore is 0.9 μm or less, the closed pore is located on the target observation surface within 0.1 mm from the ridge toward an outer edge, and the outer edge is a boundary between the outer peripheral surface of the tubular body and the target observation surface.

4. The member for a plasma processing apparatus according to claim 1, wherein the inner peripheral surface of the tubular body is a fired surface having a root mean square slope (RΔqi) of 1.3 or less.

5. The member for a plasma processing apparatus according to claim 1, wherein the inner peripheral surface of the tubular body is a fired surface having a section height difference (Rδci) of 1.7 μm or less, wherein Rδci represents a difference between a section height at a material ratio of 25% in a roughness profile and a section height at a material ratio of 75% in the roughness profile.

6. The member for a plasma processing apparatus according to claim 1, wherein the outer peripheral surface of the tubular body is a fired surface having a root mean square slope (RΔqo) of 0.04 or greater.

7. The member for a plasma processing apparatus according to claim 1, wherein the outer peripheral surface of the tubular body is a fired surface having a section height difference (Rδco) of 0.04 μm or greater, wherein Rδco represents a difference between a section height at a material ratio of 25% in a roughness profile and a section height at a material ratio of 75% in the roughness profile.

8. The member for a plasma processing apparatus according to claim 1, wherein the ceramic comprises 98 mass % or greater of the rare earth element oxide or the aluminum oxide.

9. The member for a plasma processing apparatus according to claim 8, wherein a content of the rare earth element oxide or the aluminum oxide is 99.0 mass % or greater.

10. The member for a plasma processing apparatus according to claim 1, wherein the ceramic comprises the aluminum oxide and the rare earth element aluminum composite oxide in which either the aluminum oxide or the rare earth element aluminum composite oxide is the main constituent.

11. A manufacturing method of the member for a plasma processing apparatus according to claim 1, comprising:
housing a powder, a wax, a dispersing agent, and a plasticizer in a container and stirring to obtain a slurry, the powder containing a rare earth element oxide, aluminum oxide, or a rare earth element aluminum composite oxide having a 95 vol % cumulative particle size on a cumulative distribution curve of 6.5 μm or less as a main constituent;
preheating the slurry;
defoaming the preheated slurry;
performing injection molding using the slurry to obtain a molded article having a cylindrical shape; and
firing the molded article.

12. A plasma processing apparatus comprising:
the member for a plasma processing apparatus according to claim 1; and
a plasma generating apparatus.

13. The plasma processing apparatus according to claim 12, wherein
the plasma generating apparatus comprises an upper electrode and a lower electrode disposed inside a chamber, the upper electrode including an electrode plate and a plurality of gas-flow passage tubes that are installed on the electrode plate and are configured to supply a plasma generating gas into the chamber, and
the member for a plasma processing apparatus is a gas-flow passage tube of the plurality of gas-flow passage tubes.
